(19) United States
(12) Patent Application Publication
(10) Pub. No.: US 2025/0221212 A1
(43) Pub. Date: Jul. 3, 2025

(54) TRANSPARENT DISPLAY DEVICE

(71) Applicant: LG Display Co., Ltd., Seoul (KR)

(72) Inventors: Intae Ko, Paju-si (KR); Jin-Uk Lee, Paju-si (KR); KwangHyun Baek, Paju-si (KR)

(73) Assignee: LG Display Co., Ltd., Seoul (KR)

(21) Appl. No.: 18/988,488

(22) Filed: Dec. 19, 2024

(30) Foreign Application Priority Data
Dec. 28, 2023 (KR) 10-2023-0194554

(51) Int. Cl. H10K 59/131; H10K 59/121

(52) U.S. Cl. CPC H10K 59/131; H10K 59/1213; H10K 59/1216

(57) ABSTRACT

A transparent display device can include a substrate having transmissive areas configured to transmit external light and a non-transmissive area disposed between the adjacent transmissive areas, a light emitting device disposed in the non-transmissive area on the substrate, a driving element disposed between the substrate and the light emitting device to drive the light emitting device, a first power line extending in a first direction in the non-transmissive area, and a second power line extending in a second direction in the non-transmissive area and electrically connected to the first power line. The second power line is disposed in a layer provided between the substrate and the driving element.

### CROSS-REFERENCE TO RELATED APPLICATIONS

This application claims priority to Korean Patent Application No. 10-2023-0194554, filed in the Republic of Korea on Dec. 28, 2023, the entirety of which is hereby expressly incorporated by reference into the present application.

### BACKGROUND

### Technical Field

The present disclosure relates to a transparent display device in which a transmissive area is provided in a display area.

### Discussion of the Related Art

With advancement in information-oriented societies, demands for display devices that display an image have increased in various forms. Various types of display devices such as a liquid crystal display (LCD) device, a plasma display panel (PDP) device, a Quantum dot Light Emitting Display (QLED), and an organic light emitting display (OLED) device have been widely utilized.

In recent years, there has been active research on display devices that allow users to view objects or images located on the rear surface of the display device. The transparent display device can include a display area where the images are displayed and a non-display area. The display area can include a transmissive area that can transmit external light and a non-transmissive area. In the transparent display device, a light transmittance of the display area can be determined according to a light transmittance of the transmissive area.

### BRIEF SUMMARY OF THE DISCLOSURE

The present disclosure is directed to providing a transparent display device, which substantially obviate one or more problems due to limitations and disadvantages of the related art.

An aspect of the present disclosure is directed to providing a transparent display device having a high light transmittance.

Another aspect of the present disclosure is directed to providing a transparent display device which can stably supply a source voltage and can prevent a characteristic of a driving element from being changed.

Another aspect of the present disclosure is directed to providing a transparent display device having a high transparency purity.

Another aspect of the present disclosure is directed to providing a transparent display device, which is capable of realizing ESG (Environment/Social/Governance) by reducing the generation of greenhouse gases due to the manufacturing process for producing the transparent display device.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these and other advantages and in accordance with the purpose of the disclosure, as embodied and broadly described herein, there is provided a transparent display device including a substrate including transmissive areas transmitting external light and a non-transmissive area disposed between adjacent transmissive areas, a light emitting device disposed in the non-transmissive area on the substrate, a driving element disposed between the substrate and the light emitting device to drive the light emitting device, a first power line extending in a first direction in the non-transmissive area, and a second power line extending in a second direction in the non-transmissive area and electrically connected to the first power line. The second power line is disposed in a layer provided between the substrate and the driving element.

In another aspect of the present disclosure, there is provided a transparent display device including a substrate including transmissive areas transmitting external light and a non-transmissive area disposed between adjacent transmissive areas, a driving element provided on the substrate in the non-transmissive area, a first pixel power line extending in a first direction in the non-transmissive area, a second pixel power line extending in a second direction in the non-transmissive area and electrically connected to the first pixel power line, and a common power line extending in the first direction in the non-transmissive area and disposed apart from the first pixel power line with a corresponding transmissive area therebetween, wherein the second pixel power line is disposed under the driving element.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

FIG. 1 is a perspective view schematically illustrating a transparent display device according to one or more embodiments of the present disclosure.

FIG. 2 is a plan view schematically illustrating a transparent display panel according to one or more embodiments of the present disclosure.

FIG. 3 is a diagram schematically illustrating an example of a pixel provided in a region A of FIG. 2.

FIG. 4 is a circuit diagram illustrating an example of a subpixel of FIG. 3.

FIG. 5 is a cross-sectional view illustrating an example of elements disposed in a non-transmissive area and a transmissive area of FIG. 3.

FIG. 6 is a diagram illustrating an example of a non-transmissive area according to an embodiment of the present disclosure.

FIG. 7 is a diagram illustrating an example of a transmissive area according to an embodiment of the present disclosure.

FIG. 8 is a plan view illustrating an example of a first pixel power line and a second pixel power line according to an embodiment of the present disclosure.

FIG. 9 is a cross-sectional view illustrating an example taken along line I-I′ of FIG. 8.

FIG. 10 is a cross-sectional view illustrating another example taken along line I-I′ of FIG. 8.

FIG. 11 is a plan view illustrating another example of a first pixel power line and a second pixel power line according to an embodiment of the present disclosure.

FIG. 12 is a cross-sectional view illustrating an example taken along line II-II′ of FIG. 11.

### DETAILED DESCRIPTION OF THE EMBODIMENTS

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus the present disclosure is not limited to the illustrated details. Like reference numerals refer to like elements throughout. In the following description, when the detailed description of the relevant known technology is determined to unnecessarily obscure the important point of the present disclosure, the detailed description will be omitted. In a case where “comprise,” “have,” and “include” described in the present disclosure are used, another part can be added unless “only” is used. The terms of a singular form can include plural forms unless referred to the contrary. Further, the term “can” fully encompasses all the meanings and coverages of the term “may.”

In construing an element, the element is construed as including an error range although there is no explicit description.

In describing a positional relationship, for example, when a position relation between two parts is described as “on”, “over”, “under”, and “next”, one or more other parts can be disposed between the two parts unless “just” or “direct” is used.

In describing a temporal relationship, for example, when a temporal precedence relationship is described such as “after”, “following”, “next”, “before”, etc., it can include cases that are not consecutive unless “immediately” or “directly” are used.

It will be understood that, although the terms “first,” “second,” etc. can be used herein to describe various elements, these elements should not be limited by these terms. These terms are only used to distinguish one element from another and may not necessarily define order or sequence. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure can be partially or totally coupled to or combined with each other, and can be variously inter-operated and driven technically. The embodiments of the present disclosure can be carried out independently from each other or can be carried out together with a co-dependent relationship.

Hereinafter, with reference to the accompanying drawings, one example of a display device according to the present disclosure is described. In assigning reference numerals to the components in each drawing, the same component can have the same numeral as far as possible, even if it is shown in different drawings. In addition, when the detailed description of the relevant known technology is determined to unnecessarily obscure the important point of the present disclosure, the detailed description will be omitted.

Hereinafter, embodiments of the present disclosure will be described in detail with reference to the accompanying drawings. All the components of each display device/apparatus according to all embodiments of the present disclosure are operatively coupled and configured.

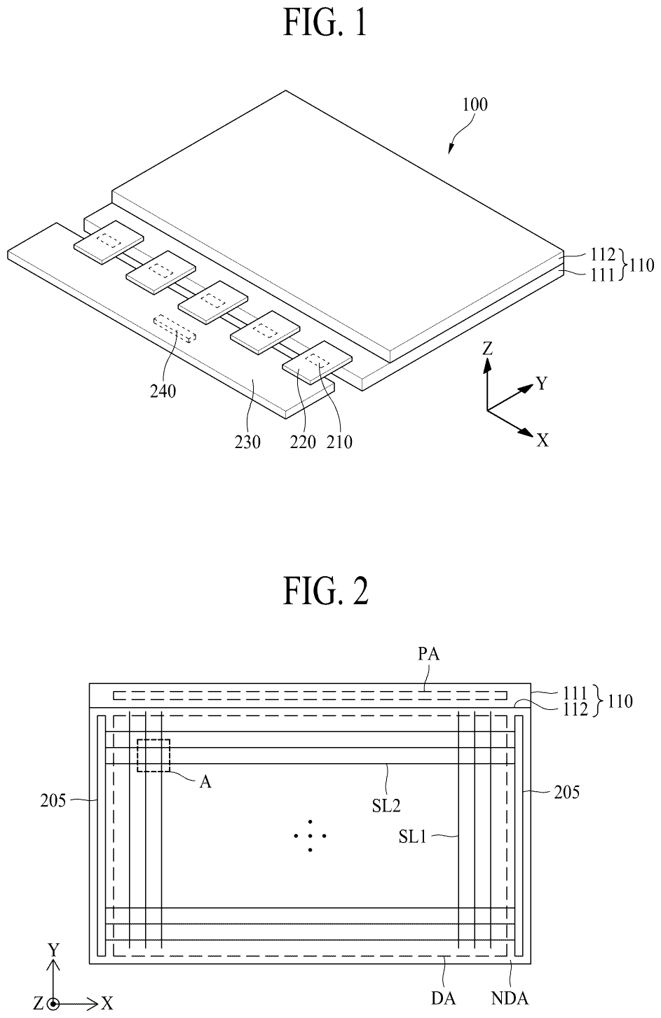

FIG. 1 is a perspective view schematically illustrating a transparent display device 100 according to one or more embodiments of the present disclosure. FIG. 2 is a plan view schematically illustrating a transparent display panel according to one or more embodiments of the present disclosure.

Herein, an X axis can represent a direction parallel to a scan line, a Y axis can represent a direction parallel to a data line, and a Z axis can represent a height of a transparent display device 100.

The transparent display device 100 according to an embodiment of the present disclosure can be mainly described as being implemented as an organic light emitting display, but is not limited thereto and can be implemented as a liquid crystal display (LCD), a plasma display panel (PDP), a quantum dot light emitting display (QLED), or an electrophoresis display.

Referring to FIGS. 1 and 2, the transparent display device 100 according to an embodiment of the present disclosure can include a transparent display panel 110, a source driving integrated circuit (IC) 210, a flexible circuit 220, a circuit board 230, and a timing controller 240.

The transparent display panel 110 can include a first substrate 111 and a second substrate 112 facing each other. The second substrate 112 can be an encapsulation substrate. The first substrate 111 can be a plastic film, a glass substrate, or a silicon wafer substrate which is formed by using a semiconductor process. The second substrate 112 can be a plastic film, a glass substrate, or an encapsulation film. The first substrate 111 and the second substrate 112 can include a transparent material.

The transparent display panel 110 can be divided into a display area DA (or active area) where pixels are provided to display an image and a non-display area NDA (or non-active area) which does not display an image. The non-display area NDA can surround the display area DA entirely or only in part(s).

First signal lines SL1, second signal lines SL2, and pixels can be provided in the display area DA, and a pad area PA where pads are disposed and at least one scan driver 205 can be provided in the non-display area NDA.

The first signal lines SL1 can extend in a first direction (for example, a Y-axis direction) and can intersect with the second signal lines SL2 in the display area DA. The second signal lines SL2 can extend in a second direction (for example, an X-axis direction) in the display area DA. The pixels can be provided in a region where the first signal line SL1 is provided or a region where the first signal line SL1 intersects with the second signal line SL2 and can emit certain light to display an image.

A plurality of pads can be disposed in the pad area PA. A size of the first substrate 111 can be greater than that of the second substrate 112, and thus, a portion of the first substrate 111 can be exposed without being covered by the second substrate 112. Pads such as power pads and data pads can be provided in a portion of the substrate 111 which is exposed without being covered by the second substrate 112.

The scan driver 205 can be connected to a scan line and can supply scan signals. The scan driver 205 can be formed as a gate driver in panel (GIP) type outside one side or both sides of the display area DA of the transparent display panel 110. Alternatively, the scan driver 205 can be manufactured as a driving chip and can be mounted on a flexible film and can be attached to the non-display area NDA outside the one side or both sides of the display area DA of the transparent display panel 110.

The source driving IC 210 can receive digital video data and a data control signal from the timing controller 240. The source driving IC 210 can convert the digital video data into analog data voltages to supply to data lines, based on the data control signal. In a case where the source driving IC 210 is manufactured as a driving chip, the source driving IC 210 can be mounted on the flexible film 220 as a chip on film (COF) type or a chip on plastic (COP) type.

Lines connecting the pads to the source driving IC 210 and lines connecting the pads to lines of the circuit board 230 can be formed in the flexible film 220. The flexible film 220 can be attached to the pads by using an anisotropic conductive film, and thus, the pads can be connected to the lines of the flexible film 220.

The circuit board 230 can be attached to flexible films 220. A plurality of circuits implemented as driving chips can be mounted on the circuit board 230. For example, the timing controller 240 can be mounted on the circuit board 230. The circuit board 150 can be a printed circuit board (PCB) or a flexible printed circuit board (FPCB).

The timing controller 240 can receive the digital video data and the timing signal from an external system board. The timing controller 240 can generate a scan control signal for controlling an operation timing of the scan driver 205 and a data control signal for controlling source driving ICs 210, based on the timing signal. The timing controller 240 can supply the scan control signal to the scan driver 205 and can supply the data control signal to the source driving ICs 210.

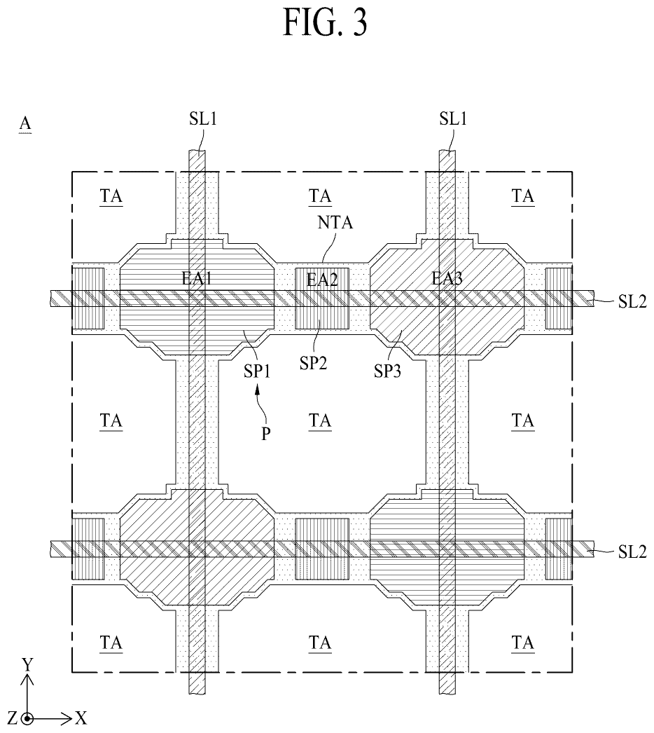

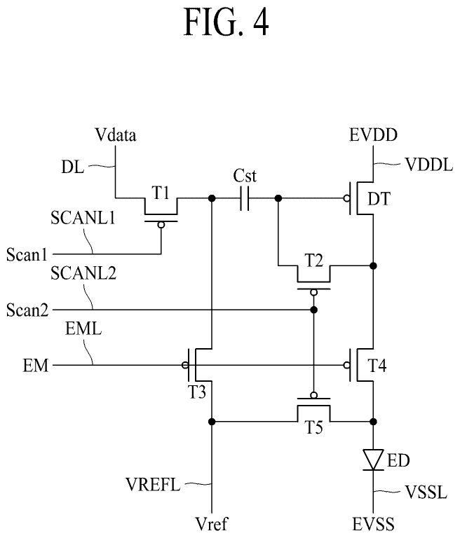

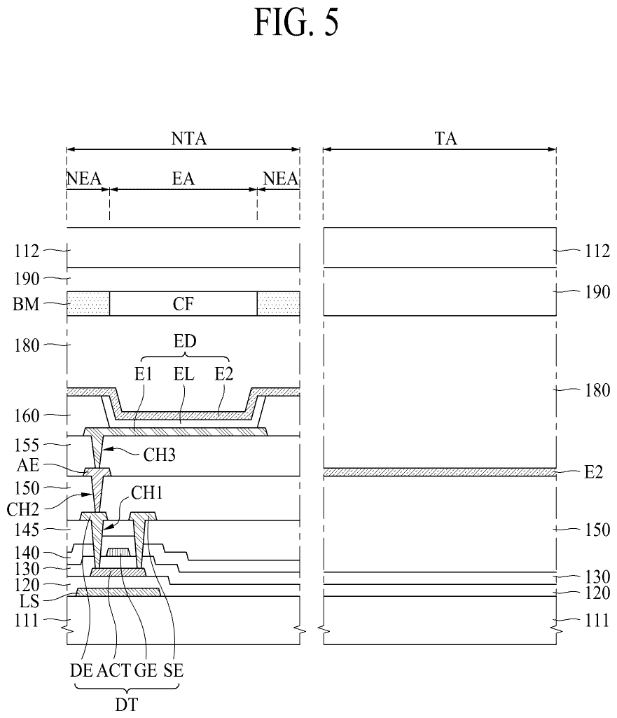

FIG. 3 is a diagram schematically illustrating an example of a pixel provided in a region A of FIG. 2. FIG. 4 is a circuit diagram illustrating an example of a subpixel of FIG. 3. FIG. 5 is a cross-sectional view illustrating an example of elements disposed in a non-transmissive area and a transmissive area of FIG. 3.

Referring to FIGS. 3 to 5, the transparent display panel 110 according to an embodiment of the present disclosure can include the display area DA and the non-display area NDA (see FIG. 2). The display area DA, as illustrated in FIG. 3, can include a first area NTA where a plurality of subpixels SP1 to SP3 are disposed and a second area TA where a plurality of subpixels SP1 to SP3 are not disposed. The first area NTA can be a non-transmissive area which does not transmit the most of light incident from the outside, and the second area TA can be a transmissive area which transmits the most of light incident from the outside.

For example, the transmissive area TA can be an area where a light transmittance is greater than α %, and the non-transmissive area NTA can be an area where a light transmittance is less than β %. Here, α can be a value which is greater than β. The transparent display panel 110 can enable a thing or a background disposed at a rear surface of the transparent display panel 110 to be seen, based on a plurality of transmissive areas TA.

The plurality of subpixels SP1 to SP3, a plurality of circuit devices, and a plurality of signal lines SL1 and SL2 can be disposed in the non-transmissive area NTA and cannot transmit light incident from the outside.

The plurality of signal lines can include first signal lines SL1 and second signal lines SL2. The first signal lines SL1 can extend in a first direction (for example, a Y-axis direction) in the non-transmissive area NTA. The first signal lines SL1 can include a pixel power line, a data line, and a common power line. In an embodiment, the first signal lines SL1 can further include a reference line.

The pixel power line can transfer a first power to a driving transistor of each of the plurality of subpixels SP1 to SP3. The common power line can transfer a second power to a cathode electrode of each of the plurality of subpixels SP1 to SP3. In this case, the second power can be a common power which is supplied to the plurality of subpixels SP1 to SP3 in common. Also, the common power line can be spaced apart from the pixel power line with a transmissive area TA therebetween.

The reference line can transfer an initialization voltage (or a reference voltage) to the driving transistor of each of the plurality of subpixels SP1 to SP3. Data lines can respectively transfer data voltages to the plurality of subpixels SP1 to SP3.

The second signal lines SL2 can extend in the second direction (for example, the X-axis direction) in the non-transmissive area NTA. The second signal line SL2 can include a scan line. The scan line can transfer a scan signal to the subpixels SP1 to SP3.

Each of the subpixels SP1 to SP3 can be included in the non-transmissive area NTA and can emit light to display an image. An emission area EA can correspond to an area, emitting light, of each of the subpixels SP1 to SP3.

The subpixels SP1 to SP3 can each be one of a first subpixel SP1 emitting light of a first color, a second subpixel SP2 emitting light of a second color, and a third subpixel SP3 emitting light of a third color, but are not limited thereto. A unit pixel P can include two or more subpixels SP1 to SP3. For example, the unit pixel P can include the first subpixel SP1, the second subpixel SP2, and the third subpixel SP3. As another example, one unit pixel P can include the first subpixel SP1 and the second subpixel SP2, and the other unit pixel P can include the second subpixel SP2 and the third subpixel SP3. Each pixel P can further include a fourth subpixel which emits white light.

The first subpixel SP1 can include a first emission area EA1 which emits light of a first color, the second subpixel SP2 can include a second emission area EA2 which emits light of a second color, and the third subpixel SP3 can include a third emission area EA3 which emits light of a third color. However, embodiments of the present disclosure are not limited thereto. Each pixel P can further include the fourth subpixel which emits white light.

For example, the first to third emission areas EA1 to EA3 can emit lights of different colors. For example, the first emission area EA1 can emit blue light, the second emission area EA2 can emit red light, and the third emission area EA3 can emit green light. An arrangement order of subpixels SP1 to SP3 can be variously changed.

Each of the first subpixel SP1, the second subpixel SP2, and the third subpixel SP3 can include a circuit device and a light emitting device. Referring to FIG. 4, each of the subpixels SP1 to SP3 can include a pixel circuit which includes a plurality of transistors DT and T1 to T5 and a light emitting device ED.

The pixel circuit illustrated in FIG. 4 can include five switching transistors T1 to T5, a driving transistor DT, a storage capacitor Cst, and a light emitting device ED, but is not limited thereto.

Each of the transistors DT and T1 to T5 of each of the subpixels SP1 to SP3 can include a gate electrode, a source electrode, and a drain electrode. The source electrode and the drain electrode cannot be fixed and can be changed based on a direction of a voltage and a current applied to the gate electrode, and thus, one of the source electrode and the drain electrode can be referred to as a first electrode, and the other can be referred to as a second electrode. The transistors DT and T1 to T5 of each of the subpixels SP1 to SP3 can use at least one of a polysilicon semiconductor, an amorphous silicon semiconductor, and an oxide semiconductor. The transistors can be a P type or an N type, or can be a combination of a P type and an N type.

A first electrode of a driving transistor DT can be connected to the pixel power line VDDL which transfers a first source voltage EVDD. A second electrode of the driving transistor DT can drive the light emitting device ED through a fourth switching transistor T4. The driving transistor DT can control a driving current, based on a driving voltage Vg of the storage capacitor Cst. Accordingly, the driving transistor DT can control an emission intensity of the light emitting device ED.

The storage capacitor Cst can be charged with a driving voltage Vg corresponding to a data voltage Vdata. The storage capacitor Cst can supply a charged driving voltage Vg to the driving transistor DT.

A first switching transistor T1 can be turned on or off in response to a first scan signal Scan1 supplied to a first scan line SCANL1. The first switching transistor T1 can supply the data voltage Vdata, supplied through a data line DL, to a first electrode of the storage capacitor Cst in response to a gate on voltage of the first scan signal Scan1.

Second and fifth switching transistors T2 and T5 can be turned on or off in response to a second scan signal Scan2 supplied to a second scan line SCANL2. The second switching transistor T2 can connect the second electrode and a gate electrode of the driving transistor DT with each other to connect the driving transistor DT in a diode structure, in response to a gate on voltage of the second scan signal Scan2. The second switching transistor T2 can charge a threshold voltage Vth of the driving transistor DT in the storage capacitor Cst to compensate for the driving transistor DT. Accordingly, the storage capacitor Cst can be charged with a data voltage “Vdata+Vth” obtained through the compensation of the threshold voltage Vth of the driving transistor DT.

The fifth switching transistor T5 can supply an initialization voltage Vref (or a reference voltage), supplied through an initialization voltage line VREFL, to an anode electrode of the light emitting device ED in response to a gate on voltage of the second scan signal Scan2.

Third and fourth switching transistors T3 and T4 can be turned on or off in response to an emission control signal EM supplied to the emission control line EML. The third switching transistor T3 can supply the initialization voltage Vref (or the reference voltage), supplied through the initialization voltage line VREFL, to the first electrode of the storage capacitor Cst in response to a gate on voltage of the emission control signal EM.

The fourth switching transistor T4 can connect the driving transistor DT to the light emitting device ED in response to a gate on voltage of the emission control signal EM. The light emitting device ED can include an anode electrode, a cathode electrode supplied with a second source voltage EVSS through the common power line VSSL, and an emission layer between the anode electrode and the cathode electrode. When a driving current is supplied from the driving transistor DT through the fourth switching transistor T4, an electron from the cathode electrode can be injected into the emission layer, a hole from the anode electrode can be injected into an organic emission layer, and a fluorescent or phosphorescent material can emit light, based on a recombination of the electron and the hole in the emission layer, and thus, the light emitting device ED can emit light having brightness proportional to a current value of the driving current.

Hereinafter, elements disposed in the non-transmissive area NTA and the transmissive area TA will be described in more detail with reference to FIG. 5.

Referring to FIG. 5, the transparent display panel 110 according to an embodiment of the present disclosure can include a first substrate 111 and a second substrate 112 facing each other, and a circuit device, the light emitting device ED, an encapsulation layer 180, a color filter CF, and a black matrix BM can be disposed between the first substrate 111 and the second substrate 112.

The circuit device can include various signal lines, a thin film transistor (TFT), and a capacitor. The signal lines can include pixel power lines, common power lines, scan lines, and data lines, and the TFT can include a switching transistor and the driving transistor DT. The switching transistor can be turned on based on a scan signal supplied to a scan line and can charge a data voltage, supplied through the data line, in the capacitor.

The driving transistor DT can be turned on based on a data voltage charged in the capacitor Cst (see FIG. 4) and can generate a data current from power supplied through the pixel power line VDDL (see FIG. 4) to supply the data current to a first electrode E1 of each of the subpixels SP1 to SP3. The driving transistor DT can include an active layer ACT, a gate electrode GE, a source electrode SE, and a drain electrode DE.

In detail, a light blocking layer LS can be provided on the first substrate 111. The light blocking layer LS can be provided to overlap a region where the driving transistor DT is formed and can block external light incident on the active layer ACT of the driving transistor DT. Also, the light blocking layer LS can be provided to overlap a region where other transistors (for example, the switching transistors T1 to T5 (see FIG. 4)) are formed and can block external light incident on an active layer of each of the switching transistors T1 to T5 (see FIG. 4).

The transparent display panel 110 can be much used in an environment which is exposed at the outside instead of the inside thereof. A time for which the transparent display panel 110 is exposed to external light can increase, and thus, a characteristic of a circuit device such as the transistors DT and T1 to T5 can be changed. Due to a change in characteristic of the circuit device, the transparent display panel 110 can decrease in luminance, and a screen can be darkened.

In the transparent display panel 110 according to an embodiment of the present disclosure, the light blocking layer LS can be disposed under the transistors DT and T1 to T5, and thus, can prevent external light from being incident on the transistors DT and T1 to T5. The transparent display panel 110 according to an embodiment of the present disclosure can prevent the characteristic of the transistors DT and T1 to T5 from being changed, and subpixels can maintain high luminance.

The light blocking layer LS can be formed of a single layer or a multilayer including one of molybdenum (Mo), aluminum (Al), chrome (Cr), gold (Au), titanium (Ti), nickel (Ni), neodymium (Nd), and copper (Cu), or an alloy thereof.

A buffer layer 120 can be provided on the light blocking layer LS. The buffer layer 120 can protect the transistors DT from water penetrating into the first substrate 111 vulnerable to water transmission. To this end, the buffer layer 120 can be included in the non-transmissive area NTA and the transmissive area TA. The buffer layer 120 can be formed of an inorganic layer, and for example, can be formed of silicon oxide (SiOx), silicon nitride (SiNx), or a multilayer thereof.

The active layer ACT of the driving transistor DT can be provided on the buffer layer 120. The active layer ACT of the driving transistor DT can include a silicon-based semiconductor material or an oxide-based semiconductor material.

A gate insulation layer 130 can be provided on the active layer ACT of the driving transistor DT. The gate insulation layer 130 can be included in the non-transmissive area NTA and the transmissive area TA. The gate insulation layer 130 can be formed of an inorganic layer, and for example, can be formed of SiOx, SiNx, or a multilayer thereof.

A gate electrode GE of the driving transistor DT can be provided on the gate insulation layer 130. The gate electrode GE of the driving transistor DT can be formed of a single layer or a multilayer including one of Mo, Al, Cr, Au, Ti, Ni, Nd, and Cu, or an alloy thereof.

A first interlayer insulation layer 140 and a second interlayer insulation layer 145 can be provided on the gate electrode GE of the driving transistor DT. To increase a light transmittance of the transmissive area TA, the first interlayer insulation layer 140 and the second interlayer insulation layer 145 can be included in only the non-transmissive area NTA and cannot be included in the transmissive area TA. Each of the first interlayer insulation layer 140 and the second interlayer insulation layer 145 can be formed of an inorganic layer, and for example, can be formed of SiOx, SiNx, or a multilayer thereof.

A source electrode SE and a drain electrode DE of the driving transistor DT can be provided on the second interlayer insulation layer 145. Each of the source electrode SE and the drain electrode DE of the driving transistor DT can be connected to the active layer ACT of the driving transistor DT through a first contact hole CH1 passing through the gate insulation layer 130, the first interlayer insulation layer 140, and the second interlayer insulation layer 145. The source electrode SE and the drain electrode DE of the driving transistor DT can be formed of a single layer or a multilayer including one of Mo, Al, Cr, Au, Ti, Ni, Nd, and Cu, or an alloy thereof.

A first planarization layer 150 can be provided on the source electrode SE and the drain electrode DE of the driving transistor DT so as to planarize a step height caused by the driving transistor DT. The first planarization layer 150 can be formed of an organic layer such as acryl resin, epoxy resin, phenolic resin, polyamide resin, or polyimide resin.

An auxiliary electrode AE can be provided on the first planarization layer 150. The auxiliary electrode AE can be connected to one of the source electrode SE and the drain electrode DE of the driving transistor DT through a second contact hole CH2 passing through the first planarization layer 150. The auxiliary electrode AE can be formed of a single layer or a multilayer including one of Mo, Al, Cr, Au, Ti, Ni, Nd, and Cu, or an alloy thereof.

A second planarization layer 155 can be provided on the auxiliary electrode AE. The second planarization layer (PLN2) 155 can be formed of an organic layer such as acryl resin, epoxy resin, phenolic resin, polyamide resin, or polyimide resin.

At least one of the first planarization layer 150 and the second planarization layer 155 can be provided in the non-transmissive area NTA and cannot be provided in at least a portion of the transmissive area TA.

In the transparent display panel 110 according to an embodiment of the present disclosure, at least one of the first planarization layer 150 and the second planarization layer 155 cannot be provided in the transmissive area TA, and thus, a light transmittance of the transmissive area TA can be enhanced.

Light emitting devices ED each including a first electrode E1, an emission layer EL, and a second electrode E2 and a bank 160 can be provided on the second planarization layer 155.

The first electrode E1 can be provided on the second planarization layer 155 and can be electrically connected to the driving transistor DT. In detail, the first electrode E1 can be connected to the auxiliary electrode AE through a third contact hole CH3 passing through the second planarization layer 155. Also, the auxiliary electrode AE can be connected to one of the source electrode SE and the drain electrode DE of the driving transistor DT through the second contact hole CH2, and the first electrode E1 can be connected to one of the source electrode SE and the drain electrode DE of the driving transistor DT through the auxiliary electrode AE.

The first electrode E1 can be included in each of the subpixels SP1 to SP3 and cannot be included in the transmissive area TA. The bank 160 can be provided between adjacent first electrodes E1, and thus, the adjacent first electrodes E1 can be electrically insulated from each other.

The first electrode E1 can include a metal material having a high reflectance such as a stack structure (Ti/Al/Ti) of aluminum and titanium, a stack structure (ITO/Al/ITO) of aluminum and indium tin oxide (ITO), an Ag alloy, a stack structure (ITO/Ag alloy/ITO) of Ag alloy and ITO, a MoTi alloy, and a stack structure (ITO/MoTi alloy/ITO) of MoTi alloy and ITO. The Ag alloy can be an alloy of Ag, palladium (Pd), and Cu. The MoTi alloy can be an alloy of Mo and Ti. The first electrode E1 can be an anode electrode.

The bank 160 can be provided on the second planarization layer 155. Also, the bank 160 can be formed to cover an edge of the first electrode E1 and expose a portion of the first electrode E1. Accordingly, the bank 160 can solve a problem where emission efficiency is reduced because current concentrate on an end of the first electrode E1.

The bank 160 can define emission areas (EA) EA1 to EA3 of the subpixels SP1 to SP3. Each of the emission areas (EA) EA1 to EA3 of the subpixels SP1 to SP3 can represent a region where the first electrode E1, the emission layer EL, and the second electrode E2 are sequentially stacked, and thus, a hole from the first electrode E1 and an electron from the second electrode E2 can be combined with each other in the emission layer EL to emit light. In this case, a region where the bank 160 is formed cannot emit light and can thus be a non-emission area NEA, and a region where the bank 160 is not formed and the first electrode E1 is exposed can be the emission areas (EA) EA1 to EA3. The bank 160 can be provided in the non-transmissive area NTA and cannot be provided in at least a portion of the transmissive area TA.

The bank 160 can be formed of an organic layer such as an acryl-based material, an epoxy-based material, a phenolic-based material, a polyamide-based material, or a polyimide-based material.

The emission layer EL can be disposed on the first electrode E1. The emission layer EL can include an emission material layer (EML) including a light emitting material. The light emitting material can include an organic material, an inorganic material, or a hybrid material. The emission layer EL can have a multi-layer structure. For example, the emission layer EL can further include at least one of a hole injection layer (HIL), a hole transport layer (HTL), an electron transport layer (ETL), and an electron injection layer (EIL). In this case, when a voltage is applied to the first electrode E1 and the second electrode E2, a hole and an electron can respectively move to an emission material layer through a hole transport layer and an electron transport layer, and can be combined with each other in the emission material layer to emit light.

In an embodiment, the emission layer EL can be a common layer which is formed in the subpixels SP1 to SP3 in common. In this case, the emission layer EL can be a white emission layer which emits white light. Here, the emission layer EL can be formed in a non-emission area NEA between the subpixels SP1 to SP3, in addition to the subpixels SP1 to SP3. The emission layer EL can be continuously formed in the subpixels SP1 to SP3 and between the subpixels SP1 to SP3. Also, the emission layer EL can be provided in the transmissive area TA as well as the non-transmissive area NTA including the emission areas EA1 to EA3 and the non-emission area NEA, but is not limited thereto. The emission layer EL can be patterned and formed in only the non-transmissive area NTA including the emission areas EA1 to EA3 and the non-emission area NEA.

In another embodiment, as illustrated in FIG. 5, in the emission layer EL, an emission material layer can be formed in each of the subpixels SP1 to SP3. For example, a green emission layer emitting green light can be formed in the first subpixel SP1, a red emission layer emitting red light can be formed in the second subpixel SP2, and a blue emission layer emitting blue light can be formed in the third subpixel SP3. In this case, the emission material layer of the emission layer EL cannot be formed in the transmissive area TA. A hole injection layer (HIL), a hole transport layer (HTL), an electron transport layer (ETL), and an electron injection layer (EIL) except the emission material layer can be formed in the subpixels SP1 to SP3 in common and can also be formed in the transmissive area TA.

The second electrode E2 can be disposed on the emission layer EL. The second electrode E2 can be a common layer which is formed in the subpixels SP1 to SP3 in common. The second electrode E2 can be formed in the non-emission area NEA between the subpixels SP1 to SP3, in addition to the emission areas (EA) EA1 to EA3. In this case, the emission layer EL can be a white emission layer which emits white light. The second electrode E2 can be continuously formed in the subpixels SP1 to SP3 and between the subpixels SP1 to SP3.

The second electrode E2 can include a transparent conductive material (TCO), such as ITO or indium zinc oxide (IZO) capable of transmitting light, or a semi-transmissive conductive material such as magnesium (Mg), Ag, or an alloy of Mg and Ag. In a case where the second electrode E2 includes a semi-transmissive conductive material, emission efficiency can be increased by a microcavity. The second electrode E2 can be a cathode electrode.

The encapsulation layer 180 can be provided on the light emitting devices ED. The encapsulation layer 180 can be formed on the second electrode E2 to cover the second electrode E2. The encapsulation layer 180 can prevent oxygen or water from penetrating into the emission layer EL and the second electrode E2. To this end, the encapsulation layer 180 can include at least one inorganic layer and at least one organic layer. The encapsulation layer 180 can be formed in a structure where an inorganic layer and an organic layer are alternately stacked, but is not limited thereto.

A color filter CF can be provided on the encapsulation layer 180. The color filter CF can be patterned and formed in each of the subpixels SP1 to SP3. In detail, the color filter CF can include a first color filter, a second color filter, and a third color filter. The first color filter can be disposed to correspond to an emission area EA1 of the first subpixel SP1 and can be a blue color filter which transmits blue light. The second color filter can be disposed to correspond to an emission area EA2 of the second subpixel SP2 and can be a red color filter which transmits red light. The third color filter can be disposed to correspond to an emission area EA3 of the third subpixel SP3 and can be a green color filter which transmits green light.

The transparent display panel 110 according to an embodiment of the present disclosure cannot use a polarizer and can include a color filter CF. When the polarizer is attached to the transparent display panel 110, a transmittance of the transparent display panel 110 can be reduced by the polarizer. Also, when the polarizer is not attached to the transparent display panel 110, a problem where light incident from the outside is reflected by electrodes can occur.

Because the polarizer is not attached, the transparent display panel 110 according to an embodiment of the present disclosure can prevent a transmittance from being reduced. Also, in the transparent display panel 110 according to an embodiment of the present disclosure, because the color filter CF is formed, the color filter CF can absorb a portion of light incident from the outside to prevent the light from being reflected by electrodes. That is, the transparent display panel 110 according to an embodiment of the present disclosure can decrease an external light reflectance without a reduction in transmittance.

A black matrix BM can be provided between color filters CF which are patterned and formed in each of the subpixels SP1 to SP3. The black matrix BM can be provided between the subpixels SP1 to SP3 and can prevent the occurrence of color mixture between adjacent subpixels SP1 to SP3. Also, the black matrix BM can prevent light incident from the outside from being reflected by a plurality of signal lines provided between the subpixels SP1 to SP3.

Moreover, the black matrix BM can be provided between the transmissive area TA and a plurality of subpixels SP1 to SP3 and can prevent light, emitted from each of the plurality of subpixels SP1 to SP3, from traveling to the transmissive area TA. Therefore, the black matrix BM can define a boundary between the transmissive area TA and the non-transmissive area NTA. In detail, the black matrix BM can define a boundary between the transmissive area TA and the non-transmissive area NTA, between the emission area EA and the transmissive area TA. In this case, in an area except the emission area EA, an area where the black matrix BM is formed can be the non-transmissive area NTA, and an area where the black matrix BM is not formed can be the transmissive area TA. That is, an area where the emission area EA and the black matrix BM are formed can be the non-transmissive area NTA, and the other area can be the transmissive area TA.

The black matrix BM can include a material which absorbs light, and for example, can include a black dye which absorbs all light of a visible light wavelength band.

The first substrate 111 including the color filter CF and the black matrix BM can be bonded to the second substrate 112 by a separate adhesive layer 190. In this case, the adhesive layer 190 can be an optically clear resin layer (OCR) or an optically clear adhesive film (OCA).

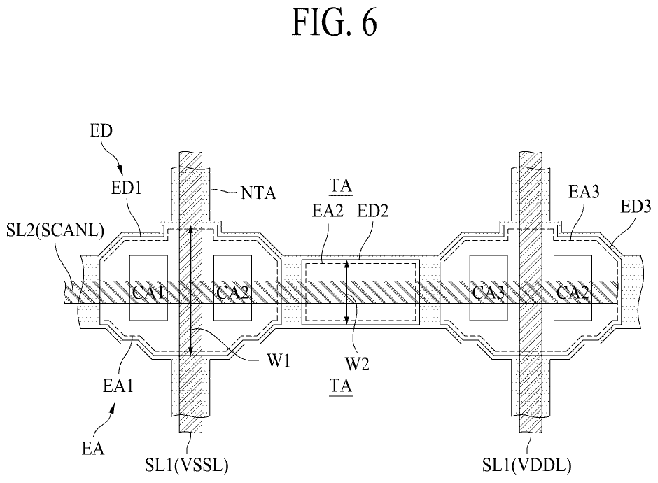

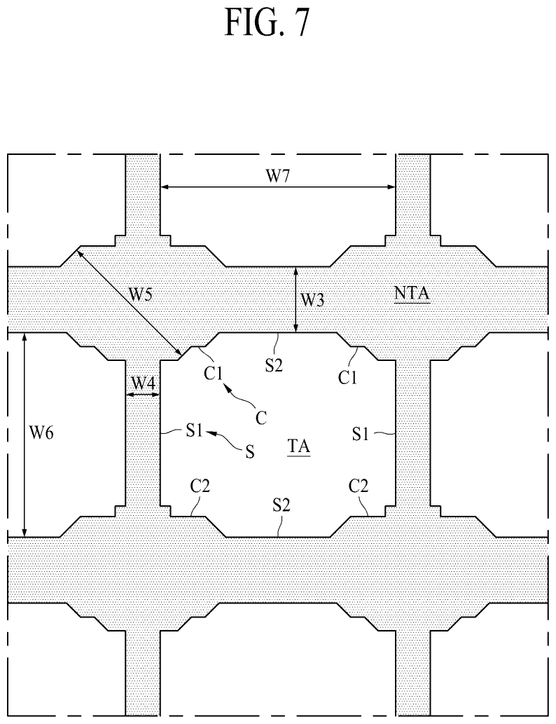

FIG. 6 is a diagram illustrating an example of a non-transmissive area according to an embodiment of the present disclosure. FIG. 7 is a diagram illustrating an example of a transmissive area according to an embodiment of the present disclosure.

Referring to FIGS. 6 and 7, the transparent display panel 110 according to an embodiment of the present disclosure can include transmissive areas TA which transmit external light and a non-transmissive area NTA which is disposed between adjacent transmissive areas TA.

The non-transmissive area NTA can include a plurality of emission areas EA which emit light of a certain color. The plurality of emission areas EA can include a first emission area EA1 which emits light of a first color, a second emission area EA2 which emits light of a second color, and a third emission area EA3 which emits light of a third color. For example, the first emission area EA1 can emit blue light, the second emission area EA2 can emit red light, and the third emission area EA3 can emit green light.

A light emitting device ED can be provided in each of a plurality of emission areas EA1 to EA3. For example, a first light emitting device ED1 emitting blue light can be provided in the first emission area EA1, a second light emitting device ED2 emitting red light can be provided in the second emission area EA2, and a third light emitting device ED3 emitting green light can be provided in the third emission area EA3.

A first signal line SL1 and a second signal line SL2 can be provided to overlap the light emitting devices ED1 to ED3 in the non-transmissive area NTA.

The first signal line SL1 can extend in the first direction (for example, the Y-axis direction) between the first substrate 111 (see FIG. 5) and the light emitting devices ED. The first signal line SL1 can include a pixel power line, and particularly, can include a first pixel power line VDDL1 and a common power line VSSL. The first pixel power line VDDL1 and the common power line VSSL can be disposed apart from each other with the transmissive area TA therebetween. One first pixel power line VDDL1 or one common power line VSSL can be disposed between transmissive areas TA adjacent to each other in the second direction (for example, the X-axis direction). The first pixel power line VDDL1 and the common power line VSSL can be alternately arranged with the transmissive area TA therebetween.

The second signal lines SL2 can extend in the second direction (for example, the X-axis direction) between the first substrate 111 (see FIG. 5) and the light emitting devices ED. The second signal line SL2 can include a scan line SCANL. The scan line SCANL can be provided as one or in plurality between transmissive areas TA adjacent to each other in the first direction (for example, the Y-axis direction). The scan line SCANL can include a first scan line SCANL1 (see FIG. 4) and a second scan line SCANL2 (see FIG. 4). The second signal line SL2 can further include an emission control line EML (see FIG. 4).

The first light emitting device ED1, the second light emitting device ED2, and the third light emitting device ED3 can be disposed to overlap at least one of the first signal line SL1 and the second signal line SL2. The first light emitting device ED1 and the third light emitting device ED3 can be disposed in a region overlapping the first signal line SL1 and the second signal line SL2.

In detail, each of the first light emitting device ED1 and the third light emitting device ED3 can be disposed in a region where at least one of the first pixel power line VDDL1 and the common power line VSSL overlaps the second signal line SL2. For example, the first light emitting device ED1 can be disposed in a region where the common power line VSSL overlaps the second signal line SL2, and the third light emitting device ED3 can be disposed in a region where the first pixel power line VDDL1 overlaps the second signal line SL2.

The first light emitting device ED1 and the third light emitting device ED3 can be arranged alternately along the first pixel power line VDDL1 and can be arranged alternately along the common power line VSSL. In this case, in a first horizontal line, the first light emitting device ED1 can be disposed in a region where the common power line VSSL overlaps the second signal line SL2, and the third light emitting device ED3 can be disposed in a region where the first pixel power line VDDL1 overlaps the second signal line SL2. Also, in a second horizontal line disposed next thereto, the first light emitting device ED1 can be disposed in a region where the first pixel power line VDDL1 overlaps the second signal line SL2, and the third light emitting device ED3 can be disposed in a region where the common power line VSSL overlaps the second signal line SL2.

The second light emitting device ED2 can be disposed between the first light emitting device ED1 and the third light emitting device ED3. The second light emitting device ED2 can be disposed in a region where the second signal line SL2 is provided, between adjacent first signal lines SL1. The second light emitting device ED2 can be disposed in a region where the second signal line SL2 is provided, between the first pixel power line VDDL1 and the common power line VSSL disposed adjacent to each other.

The first light emitting device ED1 and the third light emitting device ED3 can have a relatively wide emission area in a region where the first signal line SL1 intersects with the second signal line SL2. On the other hand, the second light emitting device ED2 can be formed to have a small area between the first light emitting device ED1 and the third light emitting device ED3.

That is, the first light emitting device ED1 and the third light emitting device ED3 can have a first area which is relatively large, and the second light emitting device ED2 can have a second area which is less than that of each of the first light emitting device ED1 and the third light emitting device ED3. Also, the first light emitting device ED1 and the third light emitting device ED3 can have a first width W1 in the first direction (for example, the Y-axis direction), and the second light emitting device ED2 can have a second width W2 which is less than that of each of the first light emitting device ED1 and the third light emitting device ED3.

Because an area of the non-transmissive area NTA is small, the transparent display panel 110 can be disposed so that a circuit device overlaps the emission areas EA1 to EA3. Particularly, the transparent display panel 110 can be disposed so that a driving element for driving the light emitting device overlaps the emission areas EA1 to EA3. The driving element can include a driving transistor DT (see FIG. 4) and a capacitor Cst (see FIG. 4).

For example, a circuit area can include a first circuit area CA1 where a first driving element connected to the first light emitting device ED1 is disposed, a second circuit area CA2 where a second driving element connected to the second light emitting device ED2 is disposed, and a third circuit area CA3 where a third driving element connected to the third light emitting device ED3 is disposed.

In the transparent display panel 110 according to an embodiment of the present disclosure, the first to third circuit areas CA1 to CA3 can be disposed to overlap the first light emitting device ED1 and the third light emitting device ED3, which have a relatively large emission area. In detail, each of the first to third circuit areas CA1 to CA3 can overlap one of the first light emitting device ED1 and the third light emitting device ED3. Each of the first to third circuit areas CA1 to CA3 cannot overlap the second light emitting device ED2.

The first circuit area CA1, as illustrated in FIG. 6, can overlap the first light emitting device ED1. A first driving element disposed in the first circuit area CA1 can overlap the first light emitting device ED1. The first driving element can be disposed at one side of the first signal line SL1 and can be electrically connected to the first light emitting device ED1.

The third circuit area CA3 can overlap the third light emitting device ED3. A third driving element disposed in the third circuit area CA3 can overlap the third light emitting device ED3. The third driving element can be disposed at the one side of the first signal line SL1 and can be electrically connected to the third light emitting device ED3.

The second circuit area CA2 can overlap one of the first light emitting device ED1 and the third light emitting device ED3. A second driving element disposed in the second circuit area CA2 can be disposed at the other side of the first signal line SL1 overlapping the first light emitting device ED1 and can be electrically connected to the second light emitting device ED2. Alternatively, a second driving element disposed in the second circuit area CA2 can be disposed at the other side of the first signal line SL1 overlapping the third light emitting device ED3 and can be electrically connected to the second light emitting device ED2.

In the transparent display panel 110 according to an embodiment of the present disclosure, the first to third driving elements can be disposed to overlap the first light emitting device ED1 and the third light emitting device ED3, and thus, a second width W2 of the second light emitting device ED2 can decrease.

The transmissive area TA can be an area which transmits the most of external light, and the light emitting device ED, the circuit device, and the signal lines SL1 and SL2 cannot be disposed in the transmissive area TA. Also, the transmissive area TA cannot overlap the color filter CF (see FIG. 5) and the black matrix BM (see FIG. 5).

The transmissive area TA, as illustrated in FIG. 7, can include a plurality of rectilinear portions S and a plurality of corner portions C.

The plurality of rectilinear portions S can be provided as a straight line which extends long to face each of the signal lines SL1 and SL2. The plurality of rectilinear portions S can include a first rectilinear portion S1 facing the first signal line SL1 and a second rectilinear portion S2 facing the second signal line SL2. The plurality of rectilinear portions S can include two first rectilinear portions S1 facing each other and two second rectilinear portions S2 facing each other.

The second light emitting device ED2 (see FIG. 6) can be provided between second rectilinear portions S2 of transmissive areas TA adjacent to each other in the first direction (for example, the Y-axis direction). In the transparent display panel 110 according to an embodiment of the present disclosure, the second driving element can be disposed to overlap the first light emitting device ED1 or the third light emitting device ED3, and thus, the second light emitting device ED2 can have a small width W2 in the first direction (for example, the Y-axis direction). Accordingly, a non-transmissive area NTA provided between the second rectilinear portions S2 of the transmissive areas TA adjacent to each other in the first direction (for example, the Y-axis direction) can have a small width W3.

In the transparent display panel 110 according to an embodiment of the present disclosure, the width W3 of the non-transmissive area NTA provided between the second rectilinear portions S2 of the transmissive areas TA can decrease, and thus, an area of the non-transmissive area NTA can decrease, and an area of the transmissive area TA can increase. Accordingly, the transparent display panel 110 according to an embodiment of the present disclosure can enhance a light transmittance of the display area DA.

Moreover, in the transparent display panel 110 according to an embodiment of the present disclosure, because the width W3 of the non-transmissive area NTA provided between the second rectilinear portions S2 of the transmissive areas TA is reduced, transparent purity can be enhanced. Here, transparent purity can represent the degree to which a user clearly recognizes, through the transmissive area TA of the transparent display panel 110, a thing or a background disposed at a rear surface. Transparent purity can be determined based on the degree of diffraction occurring periodically due to the non-transmissive area NTA in the transparent display panel 110. When the degree of diffraction increases, transparent purity can decrease, and when the degree of diffraction decreases, transparent purity can increase. The degree of diffraction can be determined based on a width of a non-transmissive area NTA provided between adjacent transmissive areas TA. As a width of a non-transmissive area NTA provided between adjacent transmissive areas TA decreases, a width of one transmissive area TA can increase, and thus, the degree of diffraction can be reduced.

In the transparent display panel 110 according to an embodiment of the present disclosure, a width W3 of a non-transmissive area NTA provided between second rectilinear portions S2 of adjacent transmissive areas TA can be reduced, and thus, a sixth width W6 between second rectilinear portions S2 facing each other in one transmissive area TA can increase. The transparent display panel 110 according to an embodiment of the present disclosure can reduce the degree to which light passing through a transmissive area TA is diffracted between second rectilinear portions S2.

In the transparent display panel 110 according to an embodiment of the present disclosure, a portion of the transmissive area TA facing the second signal line SL2 can be provided as a straight line, and thus, the third width W3 of the non-transmissive area NTA can be formed to be constant. That is, in the transparent display panel 110 according to an embodiment of the present disclosure, a width W3 of a non-transmissive area NTA provided between second rectilinear portions S2 of adjacent transmissive areas TA can be constant without being changed. Light passing through a region between second rectilinear portions S2 facing each other in one transmissive area TA can be similar or cannot be changed in degree of diffraction. In the transparent display panel 110 according to an embodiment of the present disclosure, the degree to which external light passing through the transmissive area TA is diffracted between second rectilinear portions S2 can be small, and a deviation of the degree of diffraction cannot be large or cannot occur, and thus, transparent purity can be enhanced.

A light emitting device cannot be provided between first rectilinear portions S1 of transmissive areas TA adjacent to each other in the second direction (for example, the X-axis direction). Accordingly, a non-transmissive area NTA provided between first rectilinear portions S1 of transmissive areas TA adjacent to each other in the second direction (for example, the X-axis direction) can have a fourth width W4 which is less than the third width W3.

In the transparent display panel 110 according to an embodiment of the present disclosure, a fourth width W4 of a non-transmissive area NTA provided between first rectilinear portions S1 of transmissive areas TA can minimally decrease, and thus, an area of the non-transmissive area NTA can decrease, and an area of the transmissive area TA can increase. Accordingly, the transparent display panel 110 according to an embodiment of the present disclosure can enhance a light transmittance of the display area DA.

In the transparent display panel 110 according to an embodiment of the present disclosure, because the fourth width W4 of the non-transmissive area NTA provided between the first rectilinear portions S1 of the transmissive areas TA is reduced, transparent purity can be enhanced. In detail, in the transparent display panel 110 according to an embodiment of the present disclosure, a fourth width W4 of a non-transmissive area NTA provided between first rectilinear portions S1 of adjacent transmissive areas TA can be reduced, and thus, a seventh width W7 between first rectilinear portions S1 facing each other in one transmissive area TA can increase. Accordingly, the transparent display panel 110 according to an embodiment of the present disclosure can reduce the degree to which light passing through a transmissive area TA is diffracted between first rectilinear portions S1.

In the transparent display panel 110 according to an embodiment of the present disclosure, a portion of the transmissive area TA facing the first signal line SL1 can be provided as a straight line, and thus, the fourth width W4 of the non-transmissive area NTA can be formed to be constant. That is, in the transparent display panel 110 according to an embodiment of the present disclosure, a fourth width W4 of a non-transmissive area NTA provided between first rectilinear portions S1 of adjacent transmissive areas TA can be constant without being changed. Light passing through a region between first rectilinear portions S1 facing each other in one transmissive area TA can be similar or cannot be changed in degree of diffraction. In the transparent display panel 110 according to an embodiment of the present disclosure, the degree to which external light passing through the transmissive area TA is diffracted between second rectilinear portions S2 can be small, and a deviation of the degree of diffraction cannot be large, and thus, transparent purity can increase.

Each of a plurality of corner portions C can connect rectilinear portions S with each other. In this case, the plurality of corner portions C can have a stepped shape with facing a region where the first signal line SL1 overlaps the second signal line SL2.

Furthermore, the plurality of corner portions C can have an asymmetric shape with respect to a center of the first rectilinear portion S1. In detail, the plurality of corner portions C can include a first corner portion C1 connected to one end of the first rectilinear portion S1 and a second corner portion C2 connected to the other end of the first rectilinear portion S1. The first corner portion C1 and the second corner portion C2 can have an asymmetric shape with respect to the center of the first rectilinear portion S1, but are not limited thereto.

The first light emitting device ED1 and the third emitting device ED3 can be disposed between corner portions C of adjacent transmissive areas TA. The driving elements cannot overlap the second light emitting device ED2 and can overlap the first light emitting device ED1 and the third light emitting device ED3. Accordingly, the first to third driving elements can be disposed between corner portions C of adjacent transmissive areas TA.

A fifth width W5 can be provided between corner portions C of adjacent transmissive areas TA in the third direction (for example, a diagonal direction) between the first direction (for example, the Y-axis direction) and the second direction (for example, the X-axis direction). The fifth width W5 can be greater than a third width W3 between second rectilinear portions S2 of adjacent transmissive areas TA and a fourth width W4 between first rectilinear portions S1 of adjacent transmissive areas TA. Accordingly, the fifth width W5 between corner portions C of adjacent transmissive areas TA can be largest, and thus, can largest affect the degree of diffraction of light passing through the transmissive area TA.

In the transparent display panel 110 according to an embodiment of the present disclosure, a corner portion C of a transmissive area TA can be formed in a stepped shape, and thus, can prevent an undesired increase in a non-transmissive area NTA. In a case where a transmissive area TA is formed in a circular shape, although a signal line, a circuit device, or a light emitting device cannot be provided in a corner, an area formed as a non-transmissive area NTA can occur. In the transparent display panel 110 according to an embodiment of the present disclosure, the corner portion C of the transmissive area TA can be formed in a stepped shape along an outer portion of a signal line, a circuit device, or a light emitting device, and thus, an area of the non-transmissive area NTA can be minimized. Furthermore, the transparent display panel 110 according to an embodiment of the present disclosure can minimize the fifth width W5 between corner portions C of adjacent transmissive areas TA. Accordingly, the transparent display panel 110 according to an embodiment of the present disclosure can decrease the degree to which external light passing through a transmissive area TA is diffracted between corner portions C.

Moreover, each of corner portions C of a transmissive area TA can be formed by connecting a plurality of straight lines instead of a curve. In the transparent display panel 110 according to an embodiment of the present disclosure, because corner portions C of a transmissive area TA are provided as straight lines, and thus, a variation of a fifth width W5 of a non-transmissive area NTA can be formed to be less than a case which is provided as a curve. That is, in the transparent display panel 110 according to an embodiment of the present disclosure, a variation of a fifth width W5 of a non-transmissive area NTA can slightly appear between corner portions C of adjacent transmissive area TA. Light passing through a region between corner portions C facing each other in one transmissive area TA cannot be largely changed in degree of diffraction. In the transparent display panel 110 according to an embodiment of the present disclosure, the degree to which light passing through a transmissive area TA is diffracted between corner portions C largely affecting the degree of diffraction of light can be minimized, and a deviation of the degree of diffraction can be minimized, and thus, transparent purity can more effectively increase.

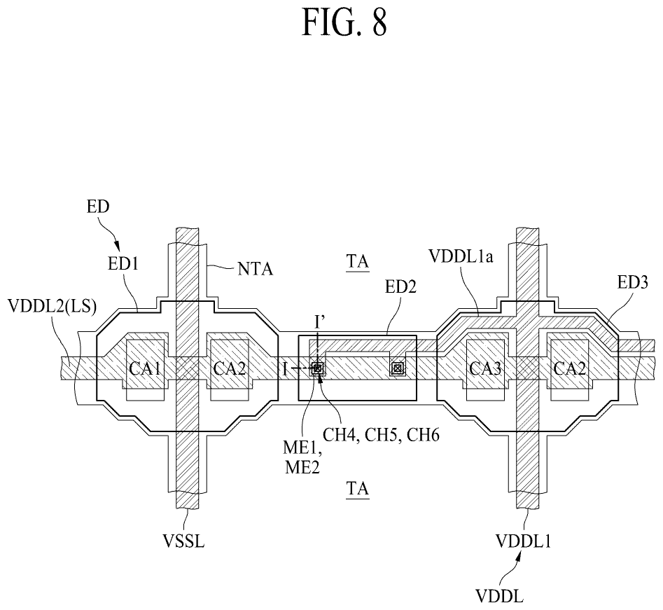

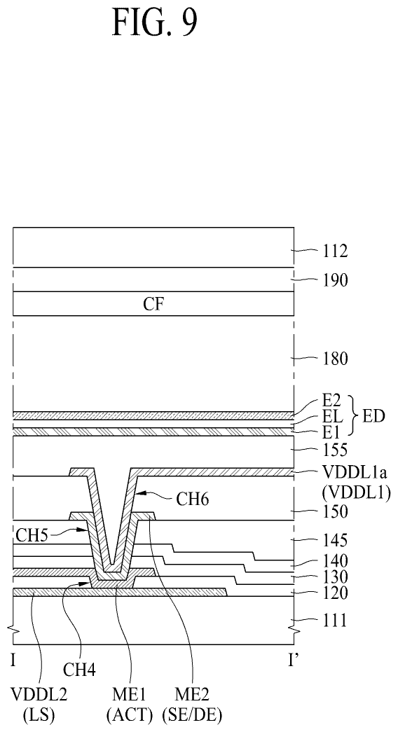

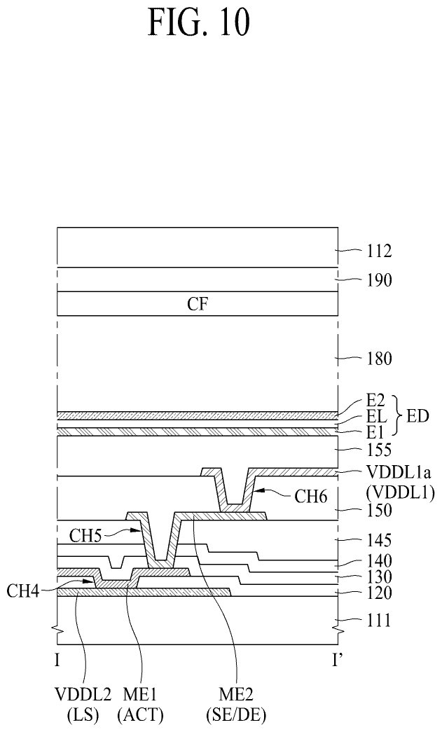

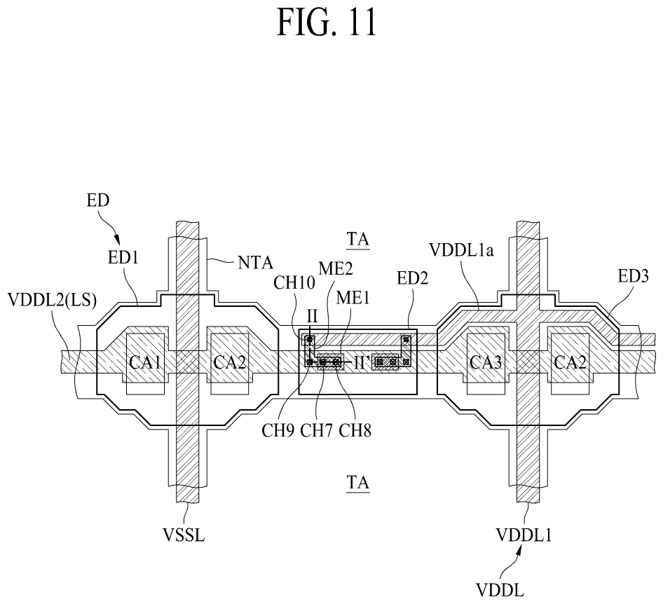

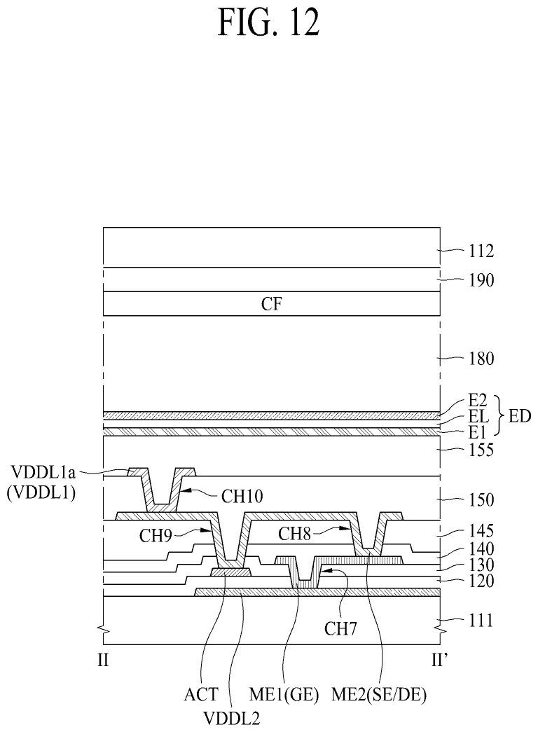

FIG. 8 is a plan view illustrating an example of a first pixel power line and a second pixel power line according to an embodiment of the present disclosure. FIG. 9 is a cross-sectional view illustrating an example taken along line I-I′ of FIG. 8. FIG. 10 is a cross-sectional view illustrating another example taken along line I-I′ of FIG. 8. FIG. 11 is a plan view illustrating another example of a first pixel power line and a second pixel power line according to an embodiment of the present disclosure. FIG. 12 is a cross-sectional view illustrating an example taken along line II-II′ of FIG. 11.

Referring to FIGS. 8 and 9, a plurality of power lines can be provided in a non-transmissive area NTA. The plurality of power lines can include a common power line VSSL and a pixel power line VDDL.

The common power line VSSL can extend in a first direction (for example, a Y-axis direction) in the non-transmissive area NTA. The common power line VSSL can transfer a second source voltage to a cathode electrode E2 of a light emitting device ED.

The pixel power line VDDL can include a first pixel power line VDDL1 and a second pixel power line VDDL2.

The first pixel power line VDDL1 can extend in the first direction (for example, the Y-axis direction) in the non-transmissive area NTA. The first pixel power line VDDL1 and the common power line VSSL can be alternately arranged with a transmissive area TA therebetween. The first pixel power line VDDL1 can supply a first source voltage to an anode electrode E1 of the light emitting device ED.

The second pixel power line VDDL2 can extend in a second direction (for example, an X-axis direction) in the non-transmissive area NTA. The second pixel power line VDDL2 can be electrically connected to the first pixel power line VDDL1. The second pixel power line VDDL2 can extend in the second direction (for example, the X-axis direction) and can be electrically connected to a plurality of first pixel power lines VDDL1. The second pixel power line VDDL2 can connect, with each other, the plurality of first pixel power lines VDDL1 disposed apart from one another, based on an equal electric potential. In a transparent display panel 110 according to an embodiment of the present disclosure, the plurality of first pixel power lines VDDL1 can be connected with each other through the second pixel power line VDDL2, and thus, a fluctuation of the first source voltage can be reduced.

The first pixel power line VDDL1 can include a connection portion VDDL1a for connecting with the second pixel power line VDDL2. The connection portion VDDL1a can protrude from one side of the first pixel power line VDDL1 and can extend in the second direction (for example, the X-axis direction), and moreover, can be electrically connected to the second pixel power line VDDL2 at one end thereof.

In the transparent display panel 110 according to an embodiment of the present disclosure, a first light emitting device ED1 can be disposed in a region where the common power line VSSL overlaps the second pixel power line VDDL2, and a third light emitting device ED3 can be disposed in a region where the first pixel power line VDDL1 overlaps the second pixel power line VDDL2. Also, in the transparent display panel 110 according to an embodiment of the present disclosure, a second light emitting device ED2 can be disposed between the first light emitting device ED1 and the third light emitting device ED3.

Moreover, in the transparent display panel 110 according to an embodiment of the present disclosure, first to third driving elements for respectively driving the first to third light emitting devices ED1 to ED3 can be disposed in only a region where the first and third light emitting devices ED1 and ED3 are formed.

For example, the second driving element and the third driving element can be disposed in a region where the third light emitting device ED3 is formed. The second driving element can be disposed at one side of the first pixel power line VDDL1, in a region where the first pixel power line VDDL1 overlaps the second pixel power line VDDL2. The third driving element can be disposed at the other side of the first pixel power line VDDL1, in a region where the first pixel power line VDDL1 overlaps the second pixel power line VDDL2. As described above, a plurality of transistors and capacitors can be disposed at a periphery of the first pixel power line VDDL1, and due to this, it cannot be easy to secure a space where contact holes for connecting the first pixel power line VDDL1 to the second pixel power line VDDL2 are to be formed. Contact holes should be formed at a periphery of the first pixel power line VDDL1 so as to connect the first pixel power line VDDL1 to the second pixel power line VDDL2 at a periphery thereof, and in this case, an area of a region where the third light emitting device ED3 is formed can increase. Due to this, an area of the non-transmissive area NTA can increase.

To prevent an increase in an area of the non-transmissive area NTA, contact holes for connecting the first pixel power line VDDL1 to the second pixel power line VDDL2 can be disposed in a region where the second light emitting device ED2 is formed. The first to third driving elements cannot be disposed in the region where the second light emitting device ED2 is formed. Accordingly, the second light emitting device ED2 can be spatially spare.

The first pixel power line VDDL1 can include a connection portion VDDL1a which protrudes from one side of the first pixel power line VDDL1 and extends in the second direction (for example, the X-axis direction), so as to contact the second pixel power line VDDL2 in a region where the second light emitting device ED2 is formed.

The first pixel power line VDDL1 and the second pixel power line VDDL2 can be provided in different layers. The first pixel power line VDDL1 can be provided on a driving element, and the second pixel power line VDDL2 can be provided under the driving element. Here, the driving element can be for driving a light emitting device and can include a driving transistor DT (see FIG. 5) and a capacitor.

The first pixel power line VDDL1 can be provided on the driving transistor DT (see FIG. 5), and the second pixel power line VDDL2 can be provided under the driving transistor DT (see FIG. 5). The first pixel power line VDDL1 can be formed in a layer provided between the light emitting device ED and the driving transistor DT (see FIG. 5). For example, the first pixel power line VDDL1 can be provided between a first planarization layer 150 and a second planarization layer 155. The first pixel power line VDDL1 can be formed of the same material in the same layer as an auxiliary electrode AE (see FIG. 5).

The second pixel power line VDDL2 can be formed in a layer provided between a first substrate 111 and the driving transistor DT (see FIG. 5). The second pixel power line VDDL2 can be provided between the first substrate 111 and a buffer layer 120. That is, the second pixel power line VDDL2 can be directly formed on the first substrate 111. The second pixel power line VDDL2 can be formed of the same material in the same layer as a light blocking layer LS. The second pixel power line VDDL2 can be provided as one body with the light blocking layer LS. The second pixel power line VDDL2 can extend in the second direction (for example, the X-axis direction) and at least a portion thereof can overlap driving transistors and capacitors included in the first to third driving elements. The second pixel power line VDDL2 can be a pixel power line and can be a light blocking layer.

The first pixel power line VDDL 1 and the second pixel power line VDDL2 can be provided in different layers and can thus be connected to each other through a contact hole. Also, a plurality of layers can be provided between the first pixel power line VDDL1 and the second pixel power line VDDL2, and due to this, it can be difficult to directly connect the first pixel power line VDDL1 to the second pixel power line VDDL2 through one contact hole. Accordingly, the first pixel power line VDDL1 and the second pixel power line VDDL2 can be electrically connected to each other through at least one middle electrodes ME1 and ME2.

In detail, the connection portion VDDL1a of the first pixel power line VDDL1 can be electrically connected to the second pixel power line VDDL2 through the at least one middle electrode ME1 and/or ME2. The at least one middle electrode ME1 and/or ME2 can electrically connect the connection portion VDDL1a of the first pixel power line VDDL1 to the second pixel power line VDDL2 through a plurality of contact holes.

For example, as illustrated in FIGS. 8 and 9, the middle electrodes ME1 and ME2 can include a first middle electrode ME1 and a second middle electrode ME2. The first middle electrode ME1 can be disposed on the second pixel power line VDDL2 and can be connected to the second pixel power line VDDL2 through a fourth contact hole CH4 passing through the buffer layer 120. The first middle electrode ME1 can be formed of the same material in the same layer as an active layer ACT of the driving transistor DT. The first middle electrode ME1 can extend toward the driving element and can be connected to the active layer ACT of the driving transistor DT.

The second middle electrode ME2 can be disposed on the first middle electrode ME1 and can be connected to the first middle electrode ME1 through a fifth contact hole CH5 passing through a gate insulation layer 130, a first interlayer insulation layer 140, and a second interlayer insulation layer 145. The fifth contact hole CH5, as illustrated in FIG. 9, can overlap the fourth contact hole CH4 in a vertical line, but is not limited thereto. The fifth contact hole CH5, as illustrated in FIG. 10, cannot overlap the fourth contact hole CH4. The fifth contact hole CH5 and the fourth contact hole CH4 can be disposed apart from each other in a plane. The second middle electrode ME2 can be formed of the same material in the same layer as a source electrode SE and a drain electrode DE of the driving transistor DT.

The connection portion VDDL1a of the first pixel power line VDDL1 can be disposed on the second middle electrode ME2 and can be connected to the second middle electrode ME2 through a sixth contact hole CH6 passing through the first planarization layer 150. The sixth contact hole CH6, as illustrated in FIG. 9, can overlap the fourth contact hole CH4 and the fifth contact hole CH5 in a vertical line, but is not limited thereto. The sixth contact hole CH6, as illustrated in FIG. 10, cannot overlap the fourth contact hole CH4 and the fifth contact hole CH5. The sixth contact hole CH6, the fourth contact hole CH4, and the fifth contact hole CH5 can be disposed apart from one another in a plane.

As another example, as illustrated in FIGS. 11 and 12, the middle electrodes ME1 and ME2 can include a first middle electrode ME1 and a second middle electrode ME2. The first middle electrode ME1 can be disposed on the second pixel power line VDDL2 and can be connected to the second pixel power line VDDL2 through a seventh contact hole CH7 passing through the buffer layer 120 and the gate insulation layer 130. The first middle electrode ME1 can be formed of the same material in the same layer as a gate electrode GE of the driving transistor DT.

The second middle electrode ME2 can be disposed on the first middle electrode MEL. The second middle electrode ME2 can be connected to the first middle electrode ME1 through an eighth contact hole CH9 passing through the first interlayer insulation layer 140 and the second interlayer insulation layer 145. The eighth contact hole CH8, as illustrated in FIG. 12, can be disposed apart from the seventh contact hole CH7 in a plane. Also, the second middle electrode ME2 can be connected to the connection portion VDDL1a of the first pixel power line VDDL1 at the other end thereof through a tenth contact hole CH10 passing through the first planarization layer 150. The second middle electrode ME2 can be connected to the active layer ACT of the driving transistor DT through a ninth contact hole CH9 passing through the gate insulation layer 130, the first interlayer insulation layer 140, and the second interlayer insulation layer 145, between the one end and the other end of the second middle electrode ME2. The second middle electrode ME2 can be formed of the same material in the same layer as the source electrode SE and the drain electrode DE of the driving transistor DT.

The connection portion VDDL1a of the first pixel power line VDDL1 can be disposed on the second middle electrode ME2 and can be connected to the second middle electrode ME2 through the tenth contact hole CH10 passing through the first planarization layer 150. The tenth contact hole CH10, as illustrated in FIG. 11, can be disposed apart from the seventh contact hole CH7 and the eighth contact hole CH8 in a plane. The tenth contact hole CH10 can be disposed in a region where the second pixel power line VDDL2 is not formed.

As a result, the connection portion VDDL1a of the first pixel power line VDDL1 can be electrically connected to the second pixel power line VDDL2 through the first middle electrode ME1 and the second middle electrode ME2.

In the transparent display panel 110 according to an embodiment of the present disclosure, a plurality of contact holes CH4 to CH9 can be disposed on the second pixel power line VDDL2. In detail, the plurality of contact holes CH4 to CH9 can be disposed on the second pixel power line VDDL2 provided in a region where the second light emitting device ED2 is formed. Also, the first middle electrode ME1 and the second middle electrode ME2 can be disposed on the second pixel power line VDDL2 provided in the region where the second light emitting device ED2 is formed.

The second pixel power line VDDL2 can be disposed at a lower portion and can support upper elements (for example, the buffer layer 120, the first middle electrode ME1, the gate insulation layer 130, the first interlayer insulation layer 140 and the second interlayer insulation layer 145, the second middle electrode ME2, the first planarization layer 150, and the connection portion VDDL1a of the first pixel power line VDDL1) and can function as an etching stopper in an etching process. Also, the second pixel power line VDDL2 can provide a flat top, and thus, the plurality of contact holes CH4 to CH9 can be precisely formed and can be formed without a defect such as an overlap even when a separation distance between the plurality of contact holes CH4 to CH9 is small.

Furthermore, the plurality of contact holes CH4 to CH9 can be disposed in a region where the second light emitting device ED2 is formed. Alternatively, the plurality of contact holes CH4 to CH9 can be disposed between the first light emitting device ED1 and the third light emitting device ED3. In this case, the plurality of contact holes CH4 to CH9 can be arranged in one row. Accordingly, the transparent display panel 110 according to an embodiment of the present disclosure can prevent a width of the second light emitting device ED2 in the first direction (for example, the Y-axis direction) from being increased by the plurality of contact holes CH4 to CH9.

The transparent display panel 110 according to an embodiment of the present disclosure can include the second pixel power line VDDL2 which connect the plurality of first pixel power lines VDDL1 with each other, and thus, a fluctuation of a first source voltage applied to the light emitting devices ED1, ED2, and ED3 through the first pixel power lines VDDL1 can decrease. Accordingly, the transparent display panel 110 according to an embodiment of the present disclosure can prevent luminance from being changed between subpixels.

Moreover, in the transparent display panel 110 according to an embodiment of the present disclosure, the second pixel power line VDDL2 can extend in the second direction (for example, the X-axis direction) and at least a portion thereof can overlap the driving elements, and thus, can prevent external light from being incident on the driving transistors and the capacitors. Accordingly, the transparent display panel 110 according to an embodiment of the present disclosure can prevent the characteristic of the transistors from being changed, and subpixels can maintain high luminance.

In the transparent display panel 110 according to an embodiment of the present disclosure, the plurality of contact holes CH4 to CH9 for connecting the first pixel power line VDDL1 to the second pixel power line VDDL2 can be arranged in one row between the first light emitting device ED1 and the third light emitting device ED3, and thus, can prevent an increase in width of the second light emitting device ED2 in the first direction (for example, the Y-axis direction). In the transparent display panel 110 according to an embodiment of the present disclosure, the second pixel power line VDDL2 can be additionally provided, and even when the plurality of contact holes CH4 to CH9 for connecting the first pixel power line VDDL1 to the second pixel power line VDDL2 are formed, the non-transmissive area NTA cannot increase. That is, in the transparent display panel 110 according to an embodiment of the present disclosure, a reduction in light transmittance caused by the second pixel power line VDDL2 cannot occur.

In the transparent display panel 110 according to an embodiment of the present disclosure, because the plurality of contact holes CH4 to CH9 are disposed on the second pixel power line VDDL2, the plurality of contact holes CH4 to CH9 can be precisely formed. Accordingly, in the transparent display panel 110 according to an embodiment of the present disclosure, the plurality of contact holes CH4 to CH9 can be formed without a defect such as an overlap even when a separation distance between the plurality of contact holes CH4 to CH9 is small.

In the transparent display panel 110 according to an embodiment of the present disclosure, as a defect rate of the plurality of contact holes CH4 to CH9 is reduced, the manufacturing process cost can decrease, and a manufacturing process time can be shortened, and moreover, production energy can be reduced. Also, in the transparent display panel 110 according to an embodiment of the present disclosure, the occurrence of a greenhouse gas caused by a manufacturing process can be reduced, thereby implementing environment/social/governance (ESG).

In the transparent display panel 110 according to an embodiment of the present disclosure, the second pixel power line VDDL2 can have a first width in a region overlapping a driving element and can have a second width which is less than the first width, in a region overlapping the plurality of contact holes CH4 to CH9. In the transparent display panel 110 according to an embodiment of the present disclosure, a width of the second pixel power line VDDL2 can be largely formed in the region overlapping the driving element, thereby effectively preventing external light from being incident on the driving element. Also, in the transparent display panel 110 according to an embodiment of the present disclosure, a width of the second pixel power line VDDL2 can be small formed in the region overlapping the plurality of contact holes CH4 to CH9, thereby preventing an increase in width of the non-transmissive area NTA in a region where the second light emitting device ED2 is provided.

The present disclosure can include a second pixel power line which connect a plurality of first pixel power lines with each other, and thus, can decrease the fluctuation of a first source voltage applied to light emitting devices through first pixel power lines. Accordingly, the present disclosure can stably supply the first source voltage to subpixels and can prevent the luminance of subpixels from being changed.

The present disclosure can include a second pixel power line where at least a portion thereof is provided to overlap driving elements, and thus, can prevent external light from being incident on driving transistors and capacitors. Accordingly, the present disclosure can prevent characteristics of driving elements from being changed, and thus, subpixels can maintain high luminance.

In the present disclosure, a plurality of contact holes for connecting a first pixel power line to a second pixel power line can be arranged in one row in a region formed between a first light emitting device and a third light emitting device, thereby preventing an increase in width of a second light emitting device. In the present disclosure, although the second pixel power line is additionally provided and the plurality of contact holes for connecting the first pixel power line to the second pixel power line are formed, a non-transmissive area cannot increase. That is, in the present disclosure, a light transmittance cannot be reduced by the second pixel power line.

In the present disclosure, the plurality of contact holes can be disposed on the second pixel power line, and thus, the plurality of contact holes can be precisely formed. In the present disclosure, although a separation distance between the plurality of contact holes is short, the plurality of contact holes can be formed without a defect such as an overlap.

As a defect rate of a plurality of contact holes is reduced, the present disclosure can decrease the manufacturing process cost and can shorten a manufacturing process time, and moreover, can reduce production energy. Also, the present disclosure can reduce the occurrence of a greenhouse gas caused by a manufacturing process and can thus implement environment/social/governance (ESG).

In the present disclosure, driving elements can be disposed in first and third subpixels having a relatively wide emission area, and thus, a width of a non-transmissive area provided between the first and third subpixels can decrease. Therefore, the present disclosure can increase an area of a transmissive area and can enhance a light transmittance. Also, in the present disclosure, as a width of the non-transmissive area provided between the first and third subpixels is reduced, the degree to which light passing through the transmissive area is diffracted can be reduced.

In the present disclosure, a portion of the transmissive area facing the non-transmissive area provided between the first and third subpixels can be configured as a rectilinear portion, and thus, a width of the non-transmissive area can be constant. Accordingly, the degree to which external light passing through the transmissive area is diffracted between rectilinear portions can be small, and a deviation of the degree of diffraction cannot be large or cannot occur, thereby enhancing a transparency purity.

In the present disclosure, corner portions of the transmissive area can be formed by connecting a plurality of straight lines with each other instead of a curve, and thus, a change in width of the non-transmissive area can slightly occur between adjacent corner portions of the transmissive area. Accordingly, the present disclosure can minimize the degree to which external light is diffracted between corner portions largely affecting the degree of diffraction, minimize a deviation of the degree of diffraction, maximize a transparency, and enhance the quality of a transparent display panel.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A transparent display device comprising:
a substrate including transmissive areas configured to transmit external light and a non-transmissive area disposed between the transmissive areas that are adjacent to each other;
a light emitting device disposed in the non-transmissive area on the substrate;
a driving element disposed between the substrate and the light emitting device to drive the light emitting device;
a first power line extending in a first direction in the non-transmissive area; and
a second power line extending in a second direction in the non-transmissive area and electrically connected to the first power line,
wherein the second power line is disposed in a layer provided between the substrate and the driving element.

2. The transparent display device of claim 1, wherein at least a portion of the second power line overlaps the driving element.

3. The transparent display device of claim 1, wherein the driving element comprises a driving transistor and a capacitor, and
wherein at least a portion of the second power line overlaps the driving transistor and the capacitor.

4. The transparent display device of claim 1, wherein the light emitting device comprises an anode electrode, an emission layer, and a cathode electrode, and
wherein the first power line comprises a first pixel power line configured to transfer a first power to the anode electrode of the light emitting device.

5. The transparent display device of claim 4, wherein the second power line comprises a second pixel power line configured to connect, with each other, a plurality of first pixel power lines disposed apart from one another, based on an equal electric potential.

6. The transparent display device of claim 1, wherein the first power line is provided in a layer, which differs from the second power line, and is electrically connected to the second power line through at least one middle electrode.

7. The transparent display device of claim 6, wherein the at least one middle electrode electrically connects the first power line to the second power line through a plurality of contact holes, and
wherein the plurality of contact holes are disposed on the second power line.

8. The transparent display device of claim 7, wherein the light emitting device comprises a first light emitting device disposed in a region where the first power line overlaps the second power line and a second light emitting device disposed in a region where only the second power line is provided, at one side of the first light emitting device, and
wherein the plurality of contact holes are disposed in a region where the second power line is provided.

9. The transparent display device of claim 7, wherein each of the transmissive areas comprises a plurality of rectilinear portions and a plurality of corner portions connecting the plurality of rectilinear portions with each other, and
wherein the plurality of contact holes are disposed between the rectilinear portions of the transmissive areas adjacent to each other in the first direction.

10. The transparent display device of claim 1, wherein the light emitting device comprises a first light emitting device disposed in a region where the first power line overlaps the second power line and a second light emitting device disposed in a region where only the second power line is provided, at one side of the first light emitting device,
wherein the driving element comprises a first driving element configured to drive the first light emitting device and a second driving element configured to drive the second light emitting device, and
wherein the first driving element and the second driving element are disposed in a region where the first light emitting device is disposed.

11. A transparent display device comprising:
a substrate including transmissive areas configured to transmit external light and a non-transmissive area disposed between the transmissive areas that are adjacent to with other;
a driving element provided on the substrate in the non-transmissive area;
a first pixel power line extending in a first direction in the non-transmissive area;
a second pixel power line extending in a second direction in the non-transmissive area and electrically connected to the first pixel power line; and
a common power line extending in the first direction in the non-transmissive area and disposed apart from the first pixel power line with a corresponding transmissive area therebetween,
wherein the second pixel power line is disposed under the driving element.

12. The transparent display device of claim 11, wherein the second pixel power line is directly disposed on the substrate.

13. The transparent display device of claim 11, wherein the first pixel power line comprises a connection portion protruding from one side thereof and extending in the second direction, the connection portion being electrically connected to the second pixel power line at one end thereof through a middle electrode.

14. The transparent display device of claim 13, wherein the middle electrode electrically connects the connection portion of the first pixel power line to the second pixel power line through a plurality of contact holes.

15. The transparent display device of claim 14, wherein the plurality of contact holes overlap the second pixel power line.

16. The transparent display device of claim 14, wherein the plurality of contact holes are arranged in one row in a region where the second pixel power line is provided.

17. The transparent display device of claim 14, wherein the second pixel power line has a first width in a region overlapping the driving element and has a second width being less than the first width, in a region overlapping the plurality of contact holes.

18. The transparent display device of claim 13, further comprising:
a first light emitting device provided in a region where the first pixel power line overlaps the second pixel power line;
a third light emitting device provided in a region where the common power line overlaps the second pixel power line; and
a second light emitting device provided between the first light emitting device and the third light emitting device.

19. The transparent display device of claim 18, wherein the connection portion of the first pixel power line is connected to the middle electrode through a first contact hole,
the middle electrode is connected to the second pixel power line through a second contact hole, and
the first contact hole and the second contact hole are disposed between the first light emitting device and the third light emitting device.

20. The transparent display device of claim 16, wherein the second pixel power line has a flat top and the plurality of contact holes are disposed on the second power line.
